(19) United States
(12) Patent Application Publication
(10) Pub. No.: US 2024/0371918 A1
(43) Pub. Date: Nov. 7, 2024

(54) METHOD (AND RELATED APPARATUS) FOR FORMING A RESISTOR OVER A SEMICONDUCTOR SUBSTRATE

(71) Applicant: Taiwan Semiconductor Manufacturing Company, Ltd., Hsinchu (TW)

(72) Inventors: Hung-Wen Hsu, Tainan City (TW); Jiech-Fun Lu, Madou Township (TW); Li-Weng Chang, Sanxia Township (TW)

(21) Appl. No.: 18/774,988

(22) Filed: Jul. 17, 2024

Related U.S. Application Data
(62) Division of application No. 17/412,456, filed on Aug. 26, 2021.

(51) Int. Cl. H01L 23/528; H01L 21/311; H01L 21/3213; H01L 23/522; H01L 27/06

(52) U.S. Cl. CPC H01L 28/20; H01L 21/31116; H01L 21/32134; H01L 23/5226; H01L 23/528; H01L 27/0688

(57) ABSTRACT

Various embodiments of the present disclosure are directed towards an integrated chip (IC). The IC comprises a substrate. A resistor overlies the substrate. The resistor comprises a resistive structure overlying the substrate. The resistor also comprises a conductive contact overlying and electrically coupled to the resistive structure. A capping structure is disposed over the conductive contact, wherein the capping structure extends laterally over an upper surface of the conductive contact and vertically along a first sidewall of the conductive contact, such that a lower surface of the capping structure is disposed below a lower surface of the conductive contact.

### REFERENCE TO RELATED APPLICATION

This Application is a Divisional of U.S. application Ser. No. 17/412,456, filed on Aug. 26, 2021, the contents of which are hereby incorporated by reference in their entirety.

### BACKGROUND

Modern integrated chips use a wide range of devices to achieve varying functionalities. In general, integrated chips comprise active devices and passive devices. Active devices include transistors (e.g., metal-oxide-semiconductor field-effect transistor (MOSFETs)), while passive devices include inductors, capacitors, and resistors. Resistors are widely used in many applications such as resistor-capacitor (RC) circuits, power drivers, power amplifiers, radio frequency (RF) applications, etc.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of an integrated chip (IC) comprising a resistor disposed over a substrate.

FIG. 2 illustrates a simplified top view of some embodiments of the IC of FIG. 1.

FIG. 3 illustrates a cross-sectional view of some other embodiments of the IC of FIG. 1.

FIG. 4 illustrates a cross-sectional view of some other embodiments of the IC of FIG. 1.

FIGS. 5A-5B through 10A-10B illustrate a series of various views of some embodiments of a method for forming an IC comprising a resistor disposed over a substrate.

FIG. 11 illustrates a flowchart of some embodiments of a method for forming an IC comprising a resistor disposed over a substrate.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Integrated chips (ICs) may have passive devices disposed over/within a substrate. The passive devices may be or comprise, for example, inductors, resistors, capacitors, diodes, or the like. One type of resistor used in an IC is a thin film resistor (TFR). A TFR comprises a resistive structure, a first conductive contact, and a second conductive contact laterally spaced from the first conductive contact. Conductive vias (e.g., metal vias) are electrically coupled to and extend vertically from the first and second conductive contacts.

Typically, a method for forming the above TFR comprises forming a resistive layer (e.g., silicon chromium (SiCr)) over the substrate. A conductive layer (e.g., titanium nitride (TIN)) is then formed over the resistive layer. A capping layer (e.g., silicon nitride (SiN)) is then formed over the conductive layer. Thereafter, the resistive layer, the conductive layer, and the capping layer are patterned to form the resistive structure, a conductive structure, and a capping structure, respectively. Outer sidewalls of the conductive structure are exposed when forming the resistive structure, the conductive structure, and the capping structure. A central portion of the capping structure is then removed (e.g., via a dry etching process) to expose a central portion of the conductive structure.

Thereafter, the central portion of the conductive structure is removed to form the first and second conductive structures on the resistive structure. Typically, the central portion of the conductive structure is removed via a wet etching process (e.g., a hydrogen peroxide (H₂O₂) wet etch)). Because of the relatively thin thickness (e.g., less than or equal to about 50 angstroms (Å)) of the resistive structure, the wet etching process is utilized because the wet etching process can be controlled to stop on the resistive structure (e.g., the resistive structure acts and an etch stop). For example, if a different type of etching process (e.g., dry etch) is utilized to remove the central portion of the capping structure, the different type of etching process may over etch the resistive structure (e.g., unintentionally remove portions of the resistive structure), thereby increasing a cost to form the IC (e.g., due to over etching of the resistive structure reducing device yield).

While the etching process is advantageous in forming the TFR due to the etching process stopping on the resistive structure, the etching process is disadvantageous in forming the TFR due to the etching process laterally etching exposed portions of the conductive structure (e.g., the H₂O₂ etch is isotropic). More specifically, the lateral etching of the conductive structure undesirably reduces the footprints (e.g., upper surface areas) of the first and second conductive contacts. The reduced footprints of the first and second conductive contacts make it more difficult to form conductive vias that are electrically coupled to the first and second conductive contacts. More specifically, the reduced footprints reduce landing zones in which the conductive vias must be formed on so that the conductive vias are electrically coupled to the first and second conductive contacts. Thus, the reduced footprints of the first and second conductive contacts may increase the cost to form the IC (e.g., due to the smaller footprints increasing misalignment issues, thereby decreasing device yield).

Various embodiments of the present application are directed toward a method for forming an integrated chip (IC). The method comprises forming a resistive layer over a substrate and a conductive layer over the resistive layer. The resistive layer and the conductive layer are then patterned to form a resistive structure and a conductive structure, respectively. A capping layer is then formed over the resistive structure and the conductive structure. The capping layer is formed covering an upper surface of the conductive structure and covering outer sidewalls of the conductive structure. The capping layer is then patterned to form capping structures that cover peripheral portions of the upper surface of the conductive structure and the outer sidewalls of the conductive structure. Patterning the capping layer also exposes a central portion of the conductive structure.

Thereafter, an etching process (e.g., a H₂O₂ wet etch) is performed to remove the central portion of the conductive structure, thereby forming first and second conductive contacts on the resistive structure. Because the capping structures cover the peripheral portions of the upper surface of the conductive structure and the outer sidewalls of the conductive structure, the capping structures prevent the etching process from laterally etching these portions of the conductive layer. Thus, the capping structures may increase the footprints of the first and second conductive contacts. Accordingly, the capping structures may reduce the cost to form the IC (e.g., due to the larger footprints decreasing misalignment issues, thereby increasing device yield).

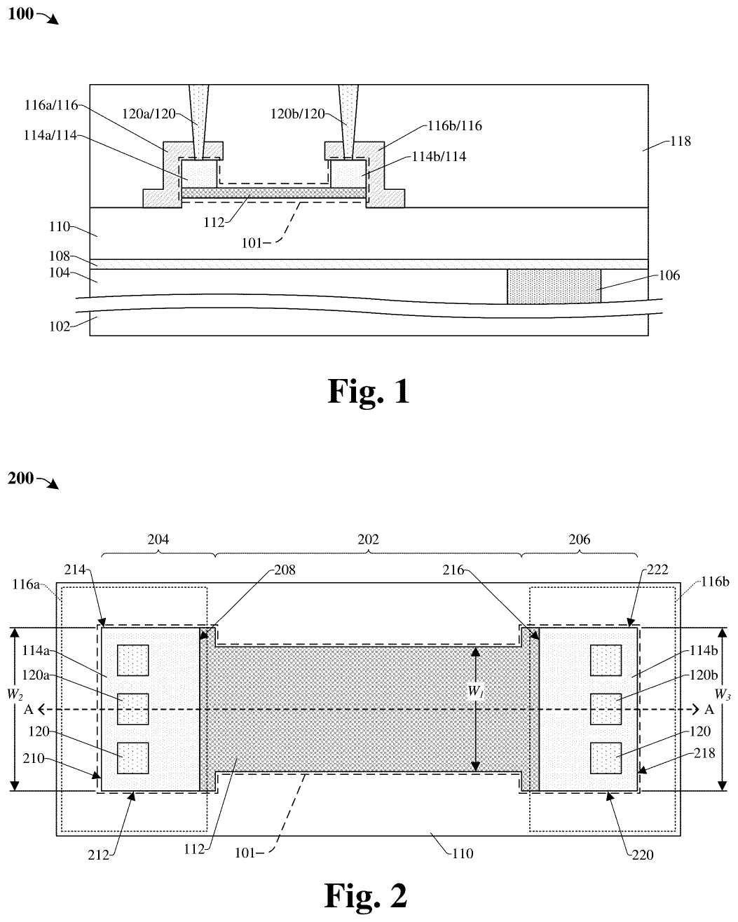

FIG. 1 illustrates a cross-sectional view 100 of some embodiments of an integrated chip (IC) comprising a resistor 101 disposed over a substrate 102.

A first inter-metal dielectric (IMD) structure 104 overlies a substrate 102. A plurality of conductive wires 106 (e.g., metal wires) are disposed within the first IMD structure 104 and overlie the substrate 102. In some embodiments, an etch stop layer 108 is disposed over the first IMD structure 104 and the conductive wires 106. A second IMD structure 110 is disposed over the first IMD structure 104 and the conductive wires 106 (and the etch stop layer 108).

A resistor 101 (e.g., a thin film resistor (TFR)) is disposed over the second IMD structure 110. The resistor 101 comprises a resistive structure 112 and a pair of conductive contacts 114. In some embodiments, the resistive structure 112 may be or comprise, for example, silicon chromium (SiCr). However, other materials for the resistive structure 112 are amenable, for example, titanium nitride (TiN), nickel chromium (NiCr), nickel chromium aluminum (NiCrAl), tantalum nitride (TaN), some other restive material suitable for a TFR, or a combination of the foregoing. The resistive structure 112 is configured to reduce current flow between the conductive contacts 114.

The conductive contacts 114 are disposed over the resistive structure 112 and laterally spaced. For example, the resistor 101 comprises a first conductive contact 114a and a second conductive contact 114b that are disposed over the resistive structure 112 and laterally spaced from one another. The conductive contacts 114 are electrically coupled to the resistive structure 112. In some embodiments, the resistor 101 may, for example, be used in resistor-capacitor (RC) circuits, power drivers, power amplifiers, radio frequency (RF) applications, analog to digital converters (ADCs), digital to analog converters (DACs), or the like.

In some embodiments, the conductive contacts 114 may be or comprises, for example, titanium nitride (TiN), tantalum nitride (TaN), some other conductive material, or a combination of the foregoing. The conductive contacts 114 comprise a different material than the resistive structure 112 (e.g., the resistive structure 112 is SiC and the conductive contacts 114 are TiN). In further embodiments, the restive structure 112 has a thickness (e.g., a vertical distance between an upper surface of the resistive structure 112 and an underlying lower surface of the resistive structure 112) between about 30 angstroms (Å) and about 60 Å. In yet further embodiments, the thickness of the resistive structure 112 is about 50 Å.

In some embodiments, the second IMD structure 110 has a first upper surface and a second upper surface. The first upper surface of the second IMD structure 110 is disposed over the second upper surface of the second IMD structure 110. In other words, the first upper surface of the second IMD structure 110 is vertically spaced from the substrate 102 by a greater distance than the second upper surface of the second IMD structure 110. In some embodiments, the resistor 101 is disposed over (e.g., directly over) the first upper surface of the second IMD structure 110, as shown in the cross-sectional view 100 of FIG. 1.

Capping structures 116 are disposed over the conductive contacts 114 and the resistive structure 112. The capping structures 116 are disposed over (e.g., directly over) the conductive contacts 114, respectively. For example, a first capping structure 116a is disposed over (e.g., directly over) the first conductive contact 114a, and a second capping structure 116b is disposed over (e.g., directly over) the second conductive contact 114b. The capping structures 116 may be or comprise, for example, a nitride (e.g., silicon nitride (SiN)), an oxy-nitride (e.g., silicon oxy-nitride (SiON)), some other dielectric material, or a combination of the foregoing. In some embodiments, each of the capping structures 116 have a thickness between about 500 Å and about 1000 Å. In other embodiments, each of the capping structures 116 may have a thickness that is greater than about 1000 Å.

The capping structures 116 extend laterally over upper surfaces of the conductive contacts 114 and vertically along sidewalls of the conductive contacts 114, respectively. For example, the first capping structure 116a extends laterally along an upper surface of the first conductive contact 114a and vertically along an outer sidewall of the first conductive contact 114a. In some embodiments, the capping structures 116 extend vertically along the outer sidewalls of the conductive contacts 114, such that lower surfaces of the capping structures 116 are disposed below lower surfaces of the conductive contacts 114, respectively. For example, the first capping structure 116a extends vertically along the outer sidewall of the first conductive contact 114a, such that the first capping structure 116a has a lower surface that is disposed below a lower surface of the first conductive contact 114a. In some embodiments, the capping structures 116 contact (e.g., directly contact) the outer sidewalls of the conductive contacts 114, respectively. In further embodiments, the capping structures 116 contact (e.g., directly contact) the second upper surface of the second IMD structure 110.

A third IMD structure 118 is disposed over the second IMD structure 110, the resistor 101, and the capping structures 116. A first plurality of conductive vias 120 (e.g., metal vias) are disposed over the conductive contacts 114 and in the third IMD structure 118. The first plurality of conductive vias 120 extend vertically through the third IMD structure 118. Further, the first plurality of conductive vias 120 extend vertically through the capping structure 116 and are electrically coupled to the conductive contacts 114. For example, a first conductive via 120a is electrically coupled to the first conductive contact 114a and extends vertically through both the third IMD structure 118 and the first capping structure 116a, and a second conductive via 120b is electrically coupled to the second conductive contact 114b and extends vertically through both the third IMD structure 118 and the second capping structure 116b.

The capping structures 116 cover (e.g., completely cover) the upper surfaces and the outer sidewalls of the conductive contacts 114. For example, the first capping structure 116a covers the upper surface of the first conductive contact 114a and the outer sidewall of the first conductive contact 114a, and the second capping structure 116b covers an upper surface of the second conductive contact 114b and an outer sidewall of the second conductive contact 114b. Because the capping structures 116 cover the outer sidewalls of the conductive contacts 114, the conductive contacts 114 may be formed with larger footprints (e.g., upper surface areas) than if the capping structures 116 did not cover the outer sidewalls of the conductive contacts 114. Because the conductive contacts 114 have increased footprints, the area (e.g., landing zones) is increased in which the first plurality of conductive vias 120 must be formed on to be electrically coupled to the conductive contacts 114. Thus, the capping structures 116 may reduce the cost to form the IC (e.g., due to the larger footprints of the conductive contacts 114 decreasing misalignment issues, thereby increasing device yield).

FIG. 2 illustrates a simplified top view 200 of some embodiments of the IC of FIG. 1. The simplified top view 200 of FIG. 2 is “simplified” because the third IMD structure 118 is omitted from the simplified top view 200 of FIG. 2. Further, for clarity, the capping structures 116 are illustrated in phantom (e.g., illustrated by dotted lines) in the simplified top view 200 of FIG. 2. The cross-sectional view 100 of FIG. 1 is taken along line A-A of FIG. 2.

As shown in the simplified top view 200 of FIG. 2, the resistive structure 112 comprises a central portion 202, a first peripheral portion 204, and a second peripheral portion 206. The central portion 202 of the resistive structure 112 has a first width W1, the first peripheral portion 204 of the resistive structure 112 has a second width W2, and the second peripheral portion 206 of the resistive structure 112 has a third width W3. The first width W1 is less than both the second width W2 and the third width W3. In some embodiments, the second width W2 is substantially the same as the third width W3, as shown in the simplified top view 200 of FIG. 2. In other embodiments, the second width W2 may be different than the third width W3. In some embodiments, the layout of the resistive structure 112 defines a layout of the resistor 101.

The first conductive contact 114a overlies the first peripheral portion 204 of the resistive structure 112. The first conductive contact 114a has a first sidewall 208, a second sidewall 210, a third sidewall 212, and a fourth sidewall 214. The first sidewall 208 of the first conductive contact 114a is opposite the second sidewall 210 of the first conductive contact 114a. The third sidewall 212 of the first conductive contact 114a is opposite the fourth sidewall 214 of the first conductive contact 114a. As shown in the simplified top view 200 of FIG. 2, in some embodiments, the second sidewall 210, the third sidewall 212, and the fourth sidewall 214 of the first conductive contact 114a are substantially aligned with corresponding sidewalls of the first peripheral portion 204 of the resistive structure 112.

The first capping structure 116a overlies the first conductive contact 114a. In some embodiments, besides the first plurality of conductive vias 120 that extend vertically through the first capping structure 116a, the first capping structure 116a covers (e.g., completely covers) an upper surface of the first conductive contact 114a. In further embodiments, the first capping structure 116a covers the first sidewall 208, the second sidewall 210, the third sidewall 212, and the fourth sidewall 214 of the first conductive contact 114a. In other words, the first capping structure 116a extends laterally over the second IMD structure 110 such that the first sidewall 208, the second sidewall 210, the third sidewall 212, and the fourth sidewall 214 of the first conductive contact 114a are disposed within an outer perimeter of the first capping structure 116a. In yet further embodiments, the first capping structure 116a may contact (e.g., directly contact) the second sidewall 210, the third sidewall 212, and/or the fourth sidewall 214 of the first conductive contact 114a. In other words, the first capping structure 116a may extend vertically along and contact (e.g., directly contact) the second sidewall 210, the third sidewall 212, and/or the fourth sidewall 214 of the first conductive contact 114a.

The second conductive contact 114b overlies the second peripheral portion 206 of the resistive structure 112. The second conductive contact 114b has a first sidewall 216, a second sidewall 218, a third sidewall 220, and a fourth sidewall 222. The first sidewall 216 of the second conductive contact 114b faces the first sidewall 208 of the first conductive contact 114a. The first sidewall 216 of the second conductive contact 114b is opposite the second sidewall 218 of the second conductive contact 114b. The third sidewall 220 of the second conductive contact 114b is opposite the fourth sidewall 222 of the second conductive contact 114b. As shown in the simplified top view 200 of FIG. 2, in some embodiments, the second sidewall 218, the third sidewall 220, and the fourth sidewall 222 of the second conductive contact 114b are substantially aligned with corresponding sidewalls of the second peripheral portion 206 of the resistive structure 112.

The second capping structure 116b overlies the second conductive contact 114b. In some embodiments, besides the first plurality of conductive vias 120 that extend vertically through the second capping structure 116b, the second capping structure 116b covers (e.g., completely covers) an upper surface of the second conductive contact 114b. In further embodiments, the second capping structure 116b covers the first sidewall 216, the second sidewall 218, the third sidewall 220, and the fourth sidewall 222 of the second conductive contact 114b. In other words, the second capping structure 116b extends laterally over the second IMD structure 110 such that the first sidewall 216, the second sidewall 218, the third sidewall 220, and the fourth sidewall 222 of the second conductive contact 114b are disposed within an outer perimeter of the second capping structure 116b. In yet further embodiments, the second capping structure 116b may contact (e.g., directly contact) the second sidewall 218, the third sidewall 220, and/or the fourth sidewall 222 of the second conductive contact 114b. In other words, the second capping structure 116b may extend vertically along and contact (e.g., directly contact) the second sidewall 218, the third sidewall 220, and/or the fourth sidewall 222 of the second conductive contact 114b.

FIG. 3 illustrates a cross-sectional view 300 of some other embodiments of the IC of FIG. 1.

As shown in the cross-sectional view 300 of FIG. 3, dielectric structures 302 are disposed over (e.g., directly over) the conductive contacts 114, respectively. For example, a first dielectric structure 302a is disposed over (e.g., directly over) the first conductive contact 114a, and a second dielectric structure 302b is disposed over (e.g., directly over) the second conductive contact 114b. The dielectric structures 302 vertically separate the capping structures 116 from the conductive contacts 114. For example, the first dielectric structure 302a vertically separates the first conductive contact 114a from the first capping structure 116a, and the second dielectric structure 302b vertically separates the second conductive contact 114b from the second capping structure 116b.

In some embodiments, the dielectric structures 302 may be or comprise, for example, a nitride (e.g., SiN), an oxy-nitride (e.g., SiON), some other dielectric material, or a combination of the foregoing. In further embodiments, the dielectric structures 302 are or comprise a different material than the capping structures 116 (e.g., the dielectric structures 302 are SION and the capping structures 116 are SiN). In other embodiments, the dielectric structures 302 and the capping structures 116 are or comprise the same material (e.g., both the dielectric structures 302 and the capping structures 116 are SiON). In some embodiments, each of the dielectric structures 302 have a thickness between about 200 Å and about 500 Å. In other embodiments, each of the dielectric structures 302 may have a thickness that is greater than about 500 Å.

In some embodiments, first sidewalls of the dielectric structures 302 are disposed between the first sidewalls of the conductive contacts 114. For example, a first sidewall 304 of the first dielectric structure 302a and a first sidewall 306 of the second dielectric structure 302b are disposed laterally between the first sidewall 208 of the first conductive contact 114a and the first sidewall 216 of the second conductive contact 114b. The first sidewall 304 of the first dielectric structure 302a faces the first sidewall 306 of the second dielectric structure 302b.

In some embodiments, the first sidewalls of the dielectric structure 302 are aligned with first sidewalls of the capping structures 116, respectively. For example, the first sidewall 304 of the first dielectric structure 302a is aligned with a first sidewall 308 of the first capping structure 116a, and the first sidewall 306 of the second dielectric structure 302b is aligned with a first sidewall 310 of the second capping structure 116b. The first sidewall 308 of the first capping structure 116a faces the first sidewall 310 of the second capping structure 116b. In some embodiments, the first sidewall 208 of the first conductive contact 114a and the first sidewall 216 of the second conductive contact 114b are laterally spaced apart a greater distance than the first sidewall 308 of the first capping structure 116a and the first sidewall 310 of the second capping structure 116b, as shown in the cross-sectional view 300 of FIG. 3.

The first sidewall 208 of the first conductive contact 114a, the first sidewall 216 of the second conductive contact 114b, the first sidewall 304 of the first dielectric structure 302a, the first sidewall 306 of the second dielectric structure 302b, the first sidewall 308 of the first capping structure 116a, and the first sidewall 310 of the second capping structure 116b are disposed laterally between a first sidewall 312 of the resistive structure 112 and a second sidewall 314 of the resistive structure 112. In some embodiments, the first sidewall 208 of the first conductive contact 114a is disposed laterally between the first sidewall 308 of the first capping structure 116a and the first sidewall 312 of the resistive structure 112. In further embodiments, the first sidewall 216 of the second conductive contact 114b is disposed laterally between the first sidewall 310 of the second capping structure 116b and the second sidewall 314 of the resistive structure 112.

In some embodiments, second sidewalls of the dielectric structures 302 are aligned with the second sidewalls of the conductive contacts 114, respectively. For example, a second sidewall 316 of the first dielectric structure 302a is aligned with the second sidewall 210 of the first conductive contact 114a, and a second sidewall 318 of the second dielectric structure 302b is aligned with the second sidewall 218 of the second conductive contact 114b. The second sidewall 316 of the first dielectric structure 302a is opposite the first sidewall 304 of the first dielectric structure 302a. The second sidewall 318 of the second dielectric structure 302b is opposite the first sidewall 306 of the second dielectric structure 302b. The second sidewall 316 of the first dielectric structure 302a and/or the second sidewall 210 of the first conductive contact 114a may be aligned with the first sidewall 312 of the resistive structure 112. The second sidewall 318 of the second dielectric structure 302b and/or the second sidewall 218 of the second conductive contact 114b may be substantially aligned with the second sidewall 314 of the resistive structure 112.

In some embodiments, cavities 320 are disposed along the first sidewalls of the conductive contacts 114, respectively. For example, a first cavity 320a is disposed along the first sidewall 208 of the first conductive contact 114a and below the first dielectric structure 302a, and a second cavity 320b is disposed along the first sidewall 216 of the second conductive contact 114b and below the second dielectric structure 302b. The first capping structure 116a overlies the first cavity 320a. The second capping structure 116b overlies the second cavity 320b. In some embodiments, the first cavity 320a extends from the third sidewall 212 of the first conductive contact 114a to the fourth sidewall 214 of the first conductive contact 114a (see, e.g., FIG. 2). In further embodiments, the second cavity 320b extends from the third sidewall 220 of the second conductive contact 114b to the fourth sidewall 222 of the second conductive contact 114b (see, e.g., FIG. 2). In yet further embodiments, each of the cavities 320 may have a width (e.g., a lateral distance from the first sidewall 208 of the first conductive contact 114a to a nearest sidewall of the third IMD structure 118) between about 1500 nanometers (nm) and about 2200 nm.

The first capping structure 116a extends vertically along the second sidewall 316 of the first dielectric structure 302a, the second sidewall 210 of the first conductive contact 114a, and the first sidewall 312 of the resistive structure 112. In some embodiments, the first capping structure 116a also extends vertically along a first sidewall 322 of the second IMD structure 110. In further embodiments, the first capping structure 116a extends vertically along the second sidewall 316 of the first dielectric structure 302a, the second sidewall 210 of the first conductive contact 114a, the first sidewall 312 of the resistive structure 112, and the first sidewall 322 of the second IMD structure 110 to contact an upper surface 324 of the second IMD structure 110.

In some embodiments, a bottom surface of the first capping structure 116a is disposed below a bottom surface of the resistive structure 112. The bottom surface of the first capping structure 116a may engage the upper surface 324 of the second IMD structure 110, as shown in the cross-sectional view 300 of FIG. 3. In further embodiments, the first capping structure 116a contacts (e.g., directly contacts) the first dielectric structure 302a, the first conductive contact 114a, the resistive structure 112, and the second IMD structure 110. More specifically, in some embodiments, the first capping structure 116a contacts (e.g., directly contacts) an upper surface of the first dielectric structure 302a, the second sidewall 316 of the first dielectric structure 302a, the second sidewall 210 of the first conductive contact 114a, the first sidewall 312 of the resistive structure 112, the first sidewall 322 of the second IMD structure 110, and the upper surface 324 of the second IMD structure 110. The first capping structure 116a extends laterally from the first sidewall 312 of the resistive structure 112 to a second sidewall 326 of the first capping structure 116a. In some embodiments, the first capping structure 116a extends laterally from the first sidewall 312 of the resistive structure 112 to the second sidewall 326 of the first capping structure 116a along the upper surface 324 of the second IMD structure 110.

The second capping structure 116b extends vertically along the second sidewall 318 of the second dielectric structure 302b, the second sidewall 218 of the second conductive contact 114b, and the second sidewall 314 of the resistive structure 112. In some embodiments, the second capping structure 116b also extends vertically along a second sidewall 328 of the second IMD structure 110. In further embodiments, the second capping structure 116b extends vertically along the second sidewall 318 of the second dielectric structure 302b, the second sidewall 218 of the second conductive contact 114b, the second sidewall 314 of the resistive structure 112, and the second sidewall 328 of the second IMD structure 110 to contact the upper surface 324 of the second IMD structure 110.

In some embodiments, a bottom surface of the second capping structure 116b is disposed below the bottom surface of the resistive structure 112. The bottom surface of the second capping structure 116b may engage the upper surface 324 of the second IMD structure 110, as shown in the cross-sectional view 300 of FIG. 3. In further embodiments, the bottom surface of the second capping structure 116b and the bottom surface of the first capping structure 116a are aligned (e.g., co-planar). In other embodiments, the bottom surface of the second capping structure 116b is disposed over or below the bottom surface of the first capping structure 116a.

In some embodiments, the second capping structure 116b contacts (e.g., directly contacts) the second dielectric structure 302b, the second conductive contact 114b, the resistive structure 112, and the second IMD structure 110. More specifically, in some embodiments, the second capping structure 116b contacts (e.g., directly contacts) an upper surface of the second dielectric structure 302b, the second sidewall 318 of the second dielectric structure 302b, the second sidewall 218 of the second conductive contact 114b, the second sidewall 314 of the resistive structure 112, the second sidewall 328 of the second IMD structure 110, and the upper surface 324 of the second IMD structure 110. The second capping structure 116b extends laterally from the second sidewall 314 of the resistive structure 112 to a second sidewall 330 of the second capping structure 116b. In some embodiments, the second capping structure 116b extends laterally from the second sidewall 314 of the resistive structure 112 to the second sidewall 330 of the second capping structure 116b along the upper surface 324 of the second IMD structure 110.

A portion of the third IMD structure 118 is disposed between (e.g., directly between) the first conductive contact 114a and the second conductive contact 114b. The portion of the third IMD structure 118 is disposed over (e.g., directly over) the resistive structure 112, laterally between the first conductive contact 114a and the second conductive contact 114b, and below an upper surface of the first conductive contact 114a and an upper surface of the second conductive contact 114b. The portion of the third IMD structure 118 is also disposed between (e.g., directly between) the cavities 320.

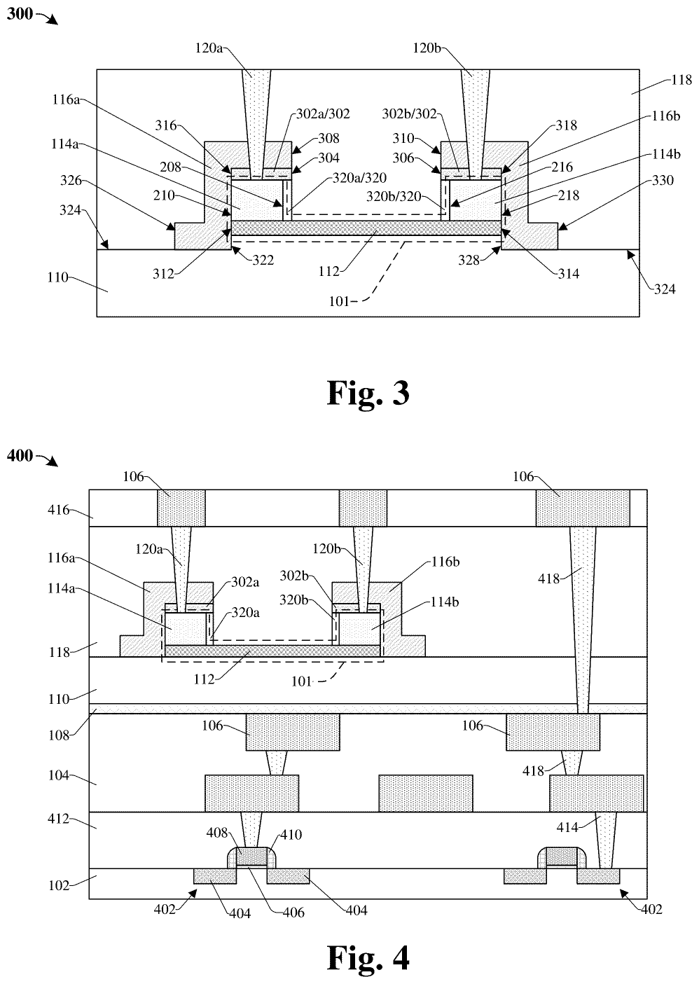

FIG. 4 illustrates a cross-sectional view 400 of some other embodiments of the IC of FIG. 1.

As shown in the cross-sectional view 400 of FIG. 4, one or more semiconductor devices 402 (e.g., insulated gate field-effect transistors (IGFETs)) are disposed within/over the substrate 102. The substrate 102 comprises any type of semiconductor body (e.g., monocrystalline silicon/CMOS bulk, germanium (Ge), silicon-germanium (SiGe), gallium arsenide (GaAs), silicon on insulator (SOI), etc.). In some embodiments, the semiconductor devices 402 each comprise source/drain regions 404, a gate dielectric layer 406, a gate electrode 408, and a sidewall spacer 410. The gate dielectric layer 406 overlies the substrate 102, and the gate electrode 408 overlies the gate dielectric layer 406. In some embodiments, the gate electrode 408 comprises polysilicon. In such embodiments, the gate dielectric layer 406 may comprise or be, for example, an oxide (e.g., SiO₂). In other embodiments, the gate electrode 408 may be or comprise a metal, such as aluminum (Al), copper (Cu), titanium (Ti), tantalum (Ta), tungsten (W), molybdenum (Mo), cobalt (Co), or the like. In such embodiments, the gate dielectric layer 406 may be or comprise a high-k dielectric material, such as hafnium oxide (HfO), tantalum oxide (TaO), hafnium silicon oxide (HfSiO), hafnium tantalum oxide (HfTaO), aluminum oxide (AlO), zirconium oxide (ZrO), or the like.

The source/drain regions 404 are disposed in the substrate 102 on opposite sides of the gate electrode 408. The source/drain regions 404 are doped regions of the substrate 102. The sidewall spacer 410 overlies the substrate and laterally surrounds the gate electrode 408. The sidewall spacer 410 may be or comprise, for example, a nitride (e.g., SiN), an oxy-nitride (e.g., SiON), an oxide (e.g., SiO₂), some other dielectric material, or a combination of the foregoing.

An interlayer dielectric (ILD) structure 412 is disposed over the substrate 102 and the semiconductor devices 402. The ILD structure 412 comprises one or more stacked ILD layers, which may respectively comprise a low-k dielectric (e.g., a dielectric material with a dielectric constant less than about 3.9), an oxide (e.g., SiO₂), an oxy-nitride (e.g., SiON), doped silicon dioxide (e.g., carbon doped silicon dioxide), borosilicate glass (BSG), phosphoric silicate glass (PSG), borophosphosilicate glass (BPSG), fluorinated silicate glass (FSG), or the like. A plurality of conductive contacts 414 are disposed over the substrate 102 and embedded in the ILD structure 412. The plurality of conductive contacts 414 may be or comprise, for example, tungsten (W), copper (Cu), aluminum (Al), some other conductive material, or a combination of the foregoing. The plurality of conductive contacts 414 extend vertically through the ILD structure 412 and are electrically coupled to the semiconductor devices 402 and/or the substrate 102.

The first IMD structure 104 is disposed over the ILD structure 412. The second IMD structure 110 is disposed over the first IMD structure 104. The third IMD structure 118 is disposed over the second IMD structure 110. A fourth IMD structure 416 is disposed over the third IMD structure 118. The first IMD structure 104, the second IMD structure 110, the third IMD structure 118, and the fourth IMD structure 416 each comprise one or more stacked IMD layers, which may respectively comprise a low-k dielectric (e.g., a dielectric material with a dielectric constant less than about 3.9), an oxide (e.g., SiO₂), an oxy-nitride (e.g., SiON), doped silicon dioxide (e.g., carbon doped silicon dioxide), borosilicate glass (BSG), phosphoric silicate glass (PSG), borophosphosilicate glass (BPSG), fluorinated silicate glass (FSG), or the like.

In some embodiments, the etch stop layer 108 is disposed between the first IMD structure 104 and the second IMD structure 110. In other embodiments, the etch stop layer 108 is omitted. The etch stop layer 108 may be or comprise, for example, a nitride (e.g., SiN), an oxy-nitride (e.g., SiON), or the like.

The resistor 101, the dielectric structures 302, and the capping structures 116 are disposed over the semiconductor devices 402 and the substrate 102. In some embodiments, the resistor 101, the dielectric structures 302, and the capping structures 116 are disposed over the etch stop layer 108. The third IMD structure 118 is disposed over the resistor 101, the dielectric structures 302, and the capping structures 116.

The plurality of conductive wires 106 are disposed in one or more of the IMD structures. For example, one or more of the plurality of conductive wires 106 are disposed in the first IMD structure 104 and the fourth IMD structure 416, as shown in the cross-sectional view 400 of FIG. 4. While not shown in the cross-sectional view 400 of FIG. 4, it will be appreciated that one or more of the plurality of conductive wires 106 may be disposed in the second IMD structure 110 and/or the third IMD structure 118. The plurality of conductive wires 106 may be or comprise, for example, copper (Cu), aluminum (Al), gold (Au), silver (Ag), some other conductive material, or a combination of the foregoing.

A second plurality of conductive vias 418 are disposed in one or more of the IMD structures. For example, one or more of the second plurality of conductive vias 418 are disposed in the first IMD structure 104, the second IMD structure 110, and the third IMD structure 118. In some embodiments, one or more of the second plurality of conductive vias 418 may also be disposed in the etch stop layer 108. In further embodiments, one or more of the second plurality of conductive vias 418 extend vertically through two or more of the IMD structures. For example, one or more of the second plurality of conductive vias 418 may extend vertically through the etch stop layer 108, the second IMD structure 110, and the third IMD structure 118. The first plurality of conductive vias 120 and the second plurality of conductive vias 418 may be or comprise, for example, copper (Cu), aluminum (Al), gold (Au), silver (Ag), some other conductive material, or a combination of the foregoing.

The plurality of conductive contacts 414, the plurality of conductive wires 106, the second plurality of conductive vias 418, the first plurality of conductive vias 120, the ILD structure 412, the first IMD structure 104, the etch stop layer 108, the second IMD structure 110, the third IMD structure 118, and the fourth IMD structure 416 are part of an interconnect structure. The interconnect structure is disposed over the substrate 102 and is configured to electrically couple the devices (e.g., the resistor 101, the semiconductor device 402, etc.) that are disposed over/within the substrate 102 together in a predefined manner. While not shown in the cross-sectional view 400 of FIG. 4, it will be appreciated that the interconnect structure may comprise any number of other conductive features (e.g., conductive lines and conductive vias) and or dielectric structures (e.g., additional ILD/IMD structures).

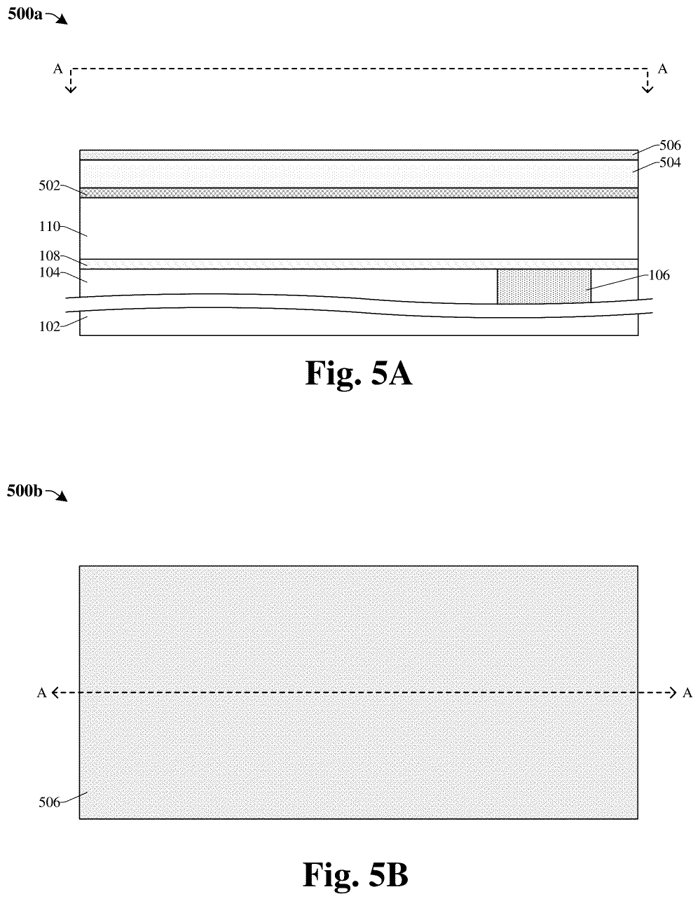

FIGS. 5A-5B through 10A-10B illustrate a series of various views of some embodiments of a method for forming an IC comprising a resistor 101 disposed over a substrate 102. Figures with a suffix of “A” (e.g., FIG. 5A) illustrate a series of cross-sectional views 500a-1000a of some embodiments for forming the IC comprising the resistor 101 disposed over the substrate 102. Figures with the suffix “B” (e.g., FIG. 5B) illustrate a series of top views 500b-1000b taken along line A-A of corresponding figures of FIGS. 5A-10A (e.g., FIG. 5B illustrates a top view 500b of the structure of FIG. 5A taken along line A-A of FIG. 5A). Although FIGS. 5A-5B through 10A-10B are described with reference to a method, it will be appreciated that the structures shown in FIGS. 5A-5B through 10A-10B are not limited to the method but rather may stand alone separate of the method.

As shown in cross-sectional view 500a of FIG. 5A and top view 500b of FIG. 5B, a substrate 102 is provided and a first inter-metal dielectric (IMD) structure 104 is formed over the substrate 102. The first IMD structure 104 may be formed by, for example, chemical vapor deposition (CVD), physical vapor deposition (PVD), atomic layer deposition (ALD), some other deposition process, or a combination of the foregoing. Thereafter, a plurality of conductive wires 106 are formed over the substrate 102 and within the first IMD structure 104. In some embodiments, the plurality of conductive wires 106 may be formed by, for example, a dual damascene process or a single damascene process. In further embodiments, the plurality of conductive wires 106 may be formed by, for example, CVD, PVD, ALD, sputtering, electrochemical plating, electroless plating, some other deposition process, or a combination of the foregoing.

In some embodiments, an etch stop layer 108 is then formed over the first IMD structure 104. The etch stop layer 108 may be formed by, for example, CVD, PVD, ALD, some other deposition process, or a combination of the foregoing. A second IMD structure 110 is then formed over the first IMD structure 104 (and the etch stop layer 108). The second IMD structure 110 may be formed by, for example, CVD, PVD, ALD, some other deposition process, or a combination of the foregoing.

Also shown in the cross-sectional view 500a of FIG. 5A and the top view 500b of FIG. 5B, a resistive layer 502 is formed over the substrate 102 and the second IMD structure 110. The resistive layer 502 may be or comprise, for example, silicon chromium (SiCr). However, other materials for the resistive layer 502 are amenable. In some embodiments, the resistive layer 502 is formed with a thickness between about 30 angstroms (Å) and about 60 Å. In further embodiments, the resistive layer 502 is formed with a thickness of about 50 Å. It will be appreciated that the resistive layer 502 may be formed with other thicknesses. In some embodiments, a process for forming the resistive layer 502 comprises depositing the resistive layer 502 on the second IMD structure 110. The resistive layer 502 may be deposited by, for example, CVD, PVD, ALD, sputtering, some other deposition process, or a combination of the foregoing.

A conductive layer 504 is then formed over the resistive layer 502. The conductive layer 504 may be or comprise, for example, titanium nitride (TiN), tantalum nitride (TaN), some other conductive material, or a combination of the foregoing. The conductive layer 504 comprise a different material than the resistive layer 502 (e.g., the resistive layer 502 is SiC and the conductive layer 504 is TiN). In some embodiments, a process for forming the conductive layer 504 comprises depositing the conductive layer 504 on the resistive layer 502. The conductive layer 504 may be deposited by, for example, CVD, PVD, ALD, sputtering, electrochemical plating, electroless plating, some other deposition process, or a combination of the foregoing.

Thereafter, a dielectric layer 506 is formed over the conductive layer 504. The dielectric layer 506 may be or comprise, for example, a nitride (e.g., SiN), an oxy-nitride (e.g., SiON), some other dielectric material, or a combination of the foregoing. In some embodiments, the dielectric layer 506 is formed with a thickness between about 200 Å and about 500 Å. In other embodiments, the dielectric layer 506 is formed with a thickness that is greater than about 500 Å. In some embodiments, a process for forming the dielectric layer 506 comprises depositing or growing the dielectric layer 506 on the conductive layer 504. The dielectric layer 506 may be deposited by, for example, CVD, PVD, ALD, thermal oxidation, some other deposition or growth process, or a combination of the foregoing.

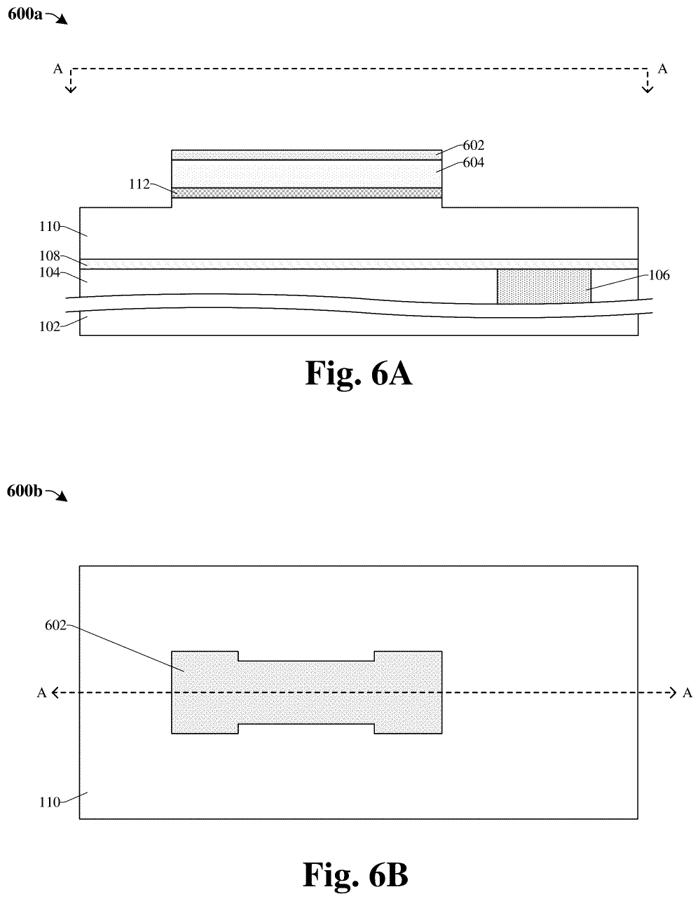

As shown in cross-sectional view 600a of FIG. 6A and top view 600b of FIG. 6B, a first patterning process is performed on the dielectric layer 506 (see, FIG. 5), the conductive layer 504 (see, FIG. 5), and the resistive layer 502 (see, FIG. 5) to form a dielectric structure 602, a first conductive structure 604, and a resistive structure 112, respectively. In some embodiments, the first patterning process comprises forming a patterned masking layer (not shown) (e.g., positive/negative photoresist, a hardmask, etc.) over the dielectric layer 506. The patterned masking layer may be formed by forming a masking layer (not shown) on the dielectric layer 506 (e.g., via a spin-on process), exposing the masking layer to a pattern (e.g., via a lithography process, such as photolithography, extreme ultraviolet lithography, or the like), and developing the masking layer, thereby forming the patterned masking layer over the dielectric layer 506. Thereafter, with the patterned masking layer in place, an etching process is performed on the dielectric layer 506, the conductive layer 504, and the resistive layer 502 to selectively etch the dielectric layer 506, the conductive layer 504, and the resistive layer 502 according to the patterned masking layer. The etching process removes unmasked portions of the dielectric layer 506, the conductive layer 504, and the resistive layer 502, thereby forming the dielectric structure 602, the first conductive structure 604, and the resistive structure 112, respectively. In some embodiments, the etching process may be, for example, a dry etching process, a reactive ion etching (RIE) process, a wet etching process, some other etching process, or a combination of the foregoing. In further embodiments, the patterned masking layer is subsequently stripped away.

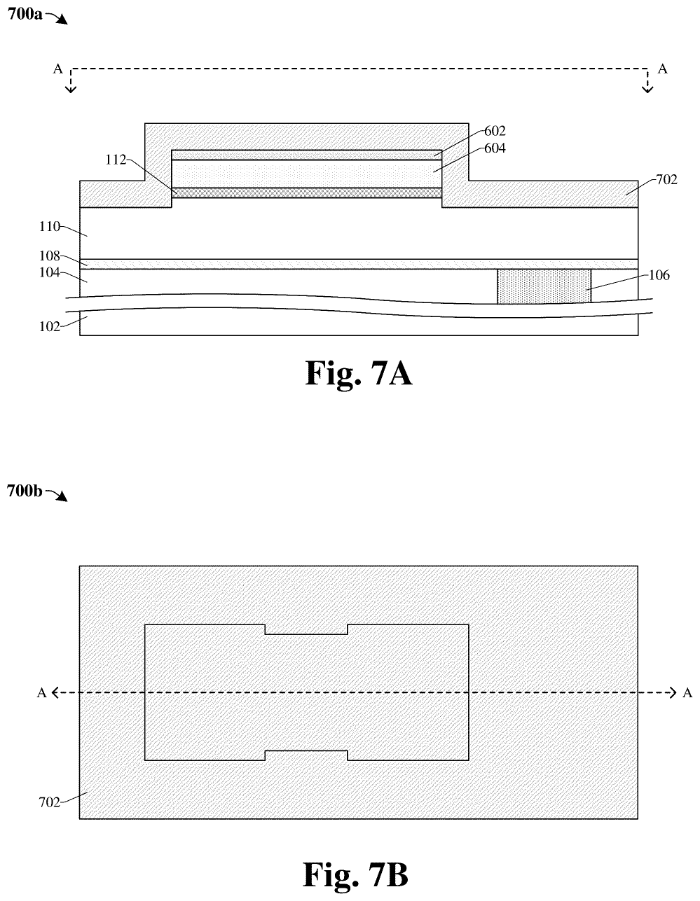

As shown in cross-sectional view 700a of FIG. 7A and top view 700b of FIG. 7B, a capping layer 702 is formed over the dielectric structure 602, the first conductive structure 604, the resistive structure 112, and the second IMD structure 110. In some embodiments, the capping layer 702 is formed on (e.g., directly on) the dielectric structure 602, the first conductive structure 604, the resistive structure 112, and the second IMD structure 110. The capping layer 702 covers (e.g., completely covers) the dielectric structure 602, the first conductive structure 604, and the resistive structure 112. The capping layer 702 is formed extending over an upper surface of the dielectric structure 602 and along sidewalls of the dielectric structure 602, the first conductive structure 604, the resistive structure 112, and the second IMD structure 110. Thus, the capping layer 702 covers the upper surface of the dielectric structure 602 and the sidewalls of the dielectric structure 602, the first conductive structure 604, the resistive structure 112, and the second IMD structure 110.

In some embodiments, the capping layer 702 is formed via a deposition process. The deposition process may be, for example, CVD, PVD, ALD, some other deposition process, or a combination of the foregoing. In further embodiments, the capping layer 702 is formed as a conformal layer.

The capping layer 702 may be or comprise, for example, a nitride (e.g., silicon nitride (SiN)), an oxy-nitride (e.g., silicon oxy-nitride (SiON)), some other dielectric material, or a combination of the foregoing. In some embodiments, the capping layer 702 has a thickness between about 500 Å and about 1000 Å. In other embodiments, the capping layer 702 may have a thickness that is greater than about 1000 Å. In some embodiments, the capping layer 702 is or comprises a different material than the dielectric structure 602 (e.g., the capping layer 702 is SiN and the dielectric structure 602 is SiON). In other embodiments, the capping layer 702 and the dielectric structure 602 comprise a same material (e.g., both the capping layer 702 and the dielectric structure 602 are SiON).

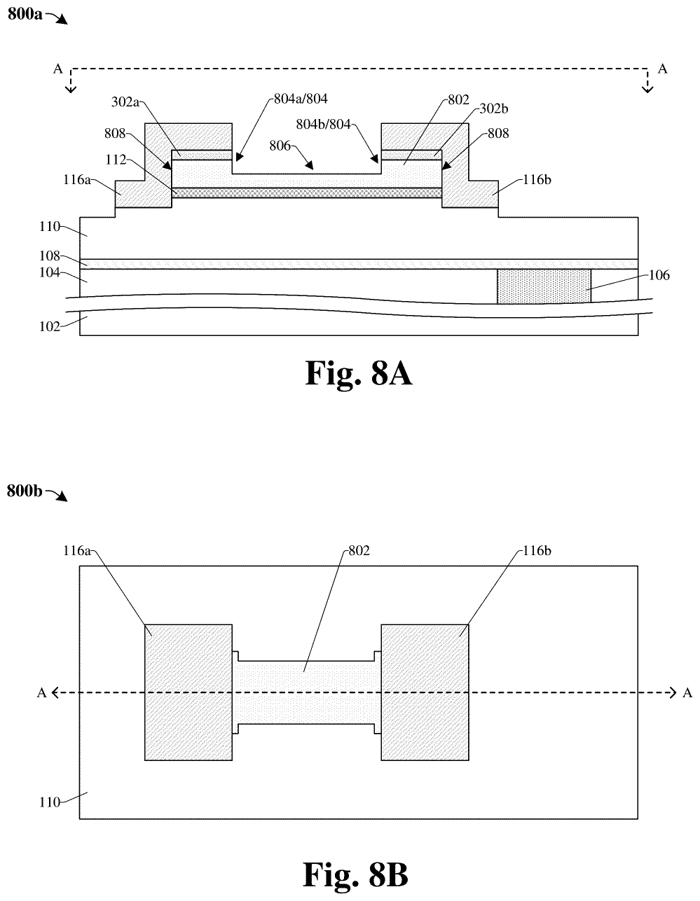

As shown in cross-sectional view 800a of FIG. 8A and top view 800b of FIG. 8B, a second patterning process is performed on the capping layer 702 (see, FIG. 7), the dielectric structure 602 (see, FIG. 7), and the first conductive structure 604 (see, FIG. 7) to form capping structures 116, dielectric structures 302, and a second conductive structure 802. More specifically, the capping layer 702 is patterned to form a first capping structure 116a and a second capping structure 116b, the dielectric structure 602 is patterned to form a first dielectric structure 302a and a second dielectric structure 302b, and the first conductive structure 604 is patterned to form the second conductive structure 802.

The capping structures 116 overlie the dielectric structures 302, respectively. The dielectric structures 302 overlie peripheral portions 804 of the second conductive structure 802, respectively. For example, the first dielectric structure 302a overlies a first peripheral portion 804a of the second conductive structure 802, and the second dielectric structure 302b overlies a second peripheral portion 804b of the second conductive structure 802. The first peripheral portion 804a of the second conductive structure 802 and the second peripheral portion 804b of the second conductive structure 802 are laterally separated by a central portion 806 of the second conductive structure 802.

The capping structures 116 cover upper surfaces of the peripheral portions 804 of the second conductive structure 802, respectively. For example, the first capping structure 116a covers an upper surface of the first peripheral portion 804a of the second conductive structure 802, and the second capping structure 116b covers an upper surface of the second peripheral portion 804b of the second conductive structure 802. In some embodiments, the capping structures 116 cover upper surfaces of the dielectric structures 302, respectively. For example, the first capping structure 116a covers an upper surface of the first dielectric structure 302a, and the second capping structure 116b covers an upper surface of the second dielectric structure 302b.

The capping structures 116 also cover sidewalls of dielectric structure 302. Further, the capping structures 116 cover sidewalls 808 of the second conductive structure 802. In some embodiments, the capping structures 116 cover sidewalls of the resistive structure 112. In further embodiments, the capping structures 116 cover the sidewalls of the second IMD structure 110 and the upper surface of the second IMD structure 110.

In some embodiments, the second patterning process comprises forming a patterned masking layer (not shown) (e.g., positive/negative photoresist, a hardmask, etc.) over the capping layer 702. The patterned masking layer may be formed by forming a masking layer (not shown) on the capping layer 702 (e.g., via a spin-on process), exposing the masking layer to a pattern (e.g., via a lithography process, such as photolithography, extreme ultraviolet lithography, or the like), and developing the masking layer, thereby forming the patterned masking layer over the capping layer 702. Thereafter, with the patterned masking layer in place, a first etching process is performed on the capping layer 702, the dielectric structure 602, and the first conductive structure 604 to selectively etch the capping layer 702, the dielectric structure 602, and the first conductive structure 604 according to the patterned masking layer. The first etching process removes unmasked portions of the capping layer 702 and unmasked portions of the dielectric structure 602, thereby forming the capping structures 116, forming the dielectric structures 302, and exposing the first conductive structure 604.

In some embodiments, the first etching process also removes an upper section of an unmasked portion of the first conductive structure 604, thereby forming the second conductive structure 802. In other embodiments, the first etching process may stop on the first conductive structure 604 (e.g., not remove a substantial portion of the first conductive structure 604) and expose an upper surface of the first conductive structure 604. In some embodiments, the first etching process also removes upper sections of unmasked portions of the second IMD structure 110, as shown in the cross-sectional view 800a of FIG. 8A and the top view 800b of FIG. 8B.

The first etching process may be, for example, dry etching process, a RIE process, a wet etching process, some other etching process, or a combination of the foregoing. More specifically, in some embodiments, the first etching process is a dry etching process that anisotropically etches the capping layer 702 and the dielectric structure 602 (and the first conductive structure 604). The first etching process is stopped before the first etching process etches through (e.g., completely through) the first conductive structure 604 to prevent over etching of the resistive structure 112. For example, the resistive structure 112 is relatively thin (e.g., less than or equal to about 50 Å), and the first etching process will etch the resistive structure 112 at least at the same rate as the first etching process etches the first conductive structure 604. Thus, if the first etching process is performed for too long, the first etching process may undesirably remove a portion of the resistive structure 112, thereby damaging the resistive structure 112 (e.g., complete or partial removal of a portion of the resistive structure 112). Accordingly, the first etching process is stopped before the first conductive structure 604 is etched through (e.g., completely through). In some embodiments, the patterned masking layer may be subsequently stripped away.

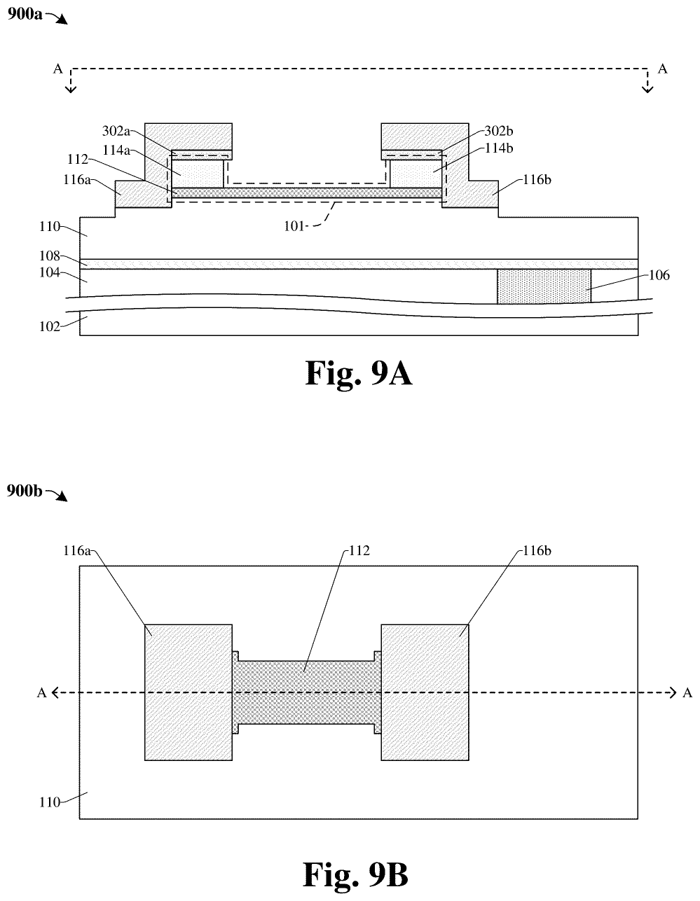

As shown in cross-sectional view 900a of FIG. 9A and top view 900b of FIG. 9B, a third patterning process is performed on the second conductive structure 802 to form conductive contacts 114 over the resistive structure 112. The third patterning process comprises performing a second etching process on the second conductive structure 802. The second etching process may be, for example, a wet etching process, a dry etching process, a RIE process, some other etching process, or a combination of the foregoing. More specifically, in some embodiments, the first etching process is a wet etching process that utilizes hydrogen peroxide (H₂O₂) as an etchant (e.g., H₂O₂ etch). In further embodiments, the wet etching process is an isotropic etching process. In some embodiments, formation of the resistor 101 is complete after the third patterning process is complete.

The second etching process removes unmasked portions of the second conductive structure 802, thereby forming the conductive contacts 114. For example, the second etching process removes the central portion 806 of the second conductive structure 802, thereby forming a first conductive contact 114a and a second conductive contact 114b. The etchants (e.g., H₂O₂) of the second etching process have a higher etch selectively for the second conductive structure 802 than the resistive structure 112. In other words, the second etching process etches the second conductive structure 802 at a faster rate (e.g., a much faster rate) than the resistive structure 112. Thus, the second etching process can be selectively stopped on the resistive structure 112 (e.g., the resistive structure 112 acts and an etch stop), thereby preventing damage to the resistive structure 112 (e.g., preventing over etching of the resistive structure 112).

The second etching process also has a higher etch selectively for the second conductive structure 802 than the dielectric structures 302 and the capping structures 116. Thus, the second etching process laterally etches the second conductive structure 802 from the central portion 806 of the second conductive structure 802 toward the peripheral portions 804 of the second conductive structure 802, such that the capping structures 116 (and the dielectric structures 302) overhang sidewalls of the conductive contacts 114. However, because the capping structures 116 cover the sidewalls 808 of the second conductive structure 802 (see, e.g., FIGS. 8A-8B), the capping structures 116 prevent the second etching process from laterally etching the sidewalls 808 of the second conductive structure 802. Thus, the capping structures 116 allow the conductive contacts 114 to be formed with larger footprints (e.g., upper surface areas) than they would be if the capping structures 116 were not covering the sidewalls 808 of the second conductive structure 802 during the second etching process.

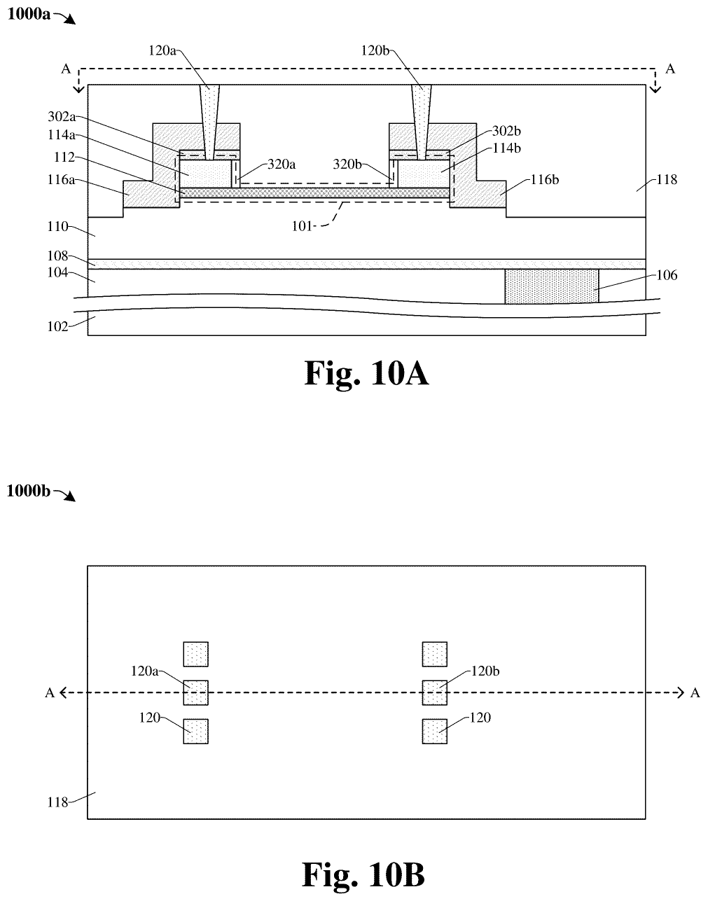

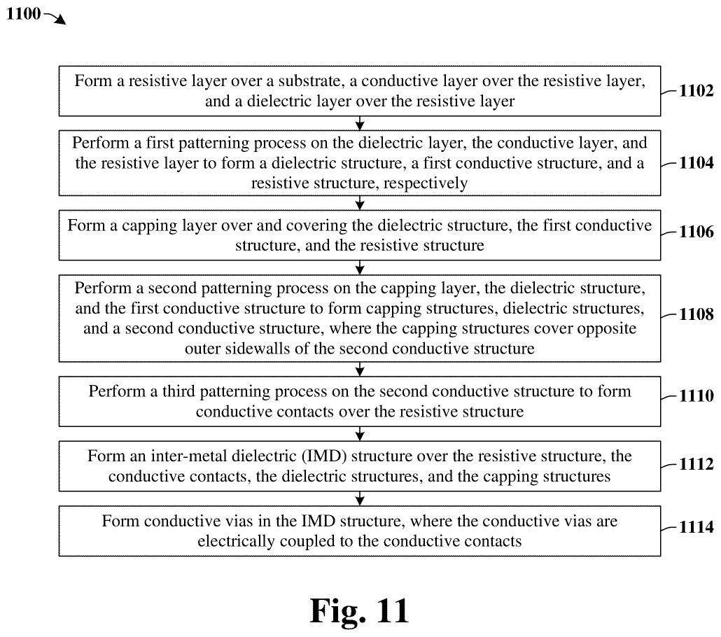

As shown in cross-sectional view 1000a of FIG. 10A and top view 1000b of FIG. 10B, a third IMD structure 118 is formed over the resistor 101, the second IMD structure 110, the dielectric structures 302, and the capping structures 116. Also shown in the cross-sectional view 1000a of FIG. 10A and the top view 1000b of FIG. 10B, a first plurality of conductive vias 120 are formed over the conductive contacts 114 and in the third IMD structure 118. The first plurality of conductive vias 120 extend vertically through the dielectric structures 302 and the third IMD structure 118. The first plurality of conductive vias 120 are electrically coupled to the conductive contacts 114. For example, a first conductive via 120a is electrically coupled to the first conductive contact 114a, and a second conductive via 120b is electrically coupled to the second conductive contact 114b.

In some embodiments, a process for forming the third IMD structure 118 and the first plurality of conductive vias 120 comprises depositing an IMD layer (not shown) over the resistor 101, the second IMD structure 110, the dielectric structures 302, and the capping structures 116. The IMD layer may be or comprise, for example, a low-k dielectric (e.g., a dielectric material with a dielectric constant less than about 3.9), an oxide (e.g., SiO₂), an oxy-nitride (e.g., SiON), doped silicon dioxide (e.g., carbon doped silicon dioxide), borosilicate glass (BSG), phosphoric silicate glass (PSG), borophosphosilicate glass (BPSG), fluorinated silicate glass (FSG), or the like. The IMD layer may be deposited by, for example, CVD, PVD, ALD, some other deposition process, or a combination of the foregoing. In some embodiments, because the capping structures 116 (and the dielectric structures 302) overhang the sidewalls of the conductive contacts 114 (e.g., due to the second etching process laterally etching the second conductive structure 802), the IMD layer may not be deposited vertically between (e.g., directly between) the resistive structure 112 and the dielectric structures 302, thereby resulting in cavities 320 being formed vertically between (e.g., directly between) the resistive structure 112 and the dielectric structures 302. For example, a first cavity 320a may be formed along a sidewall of the first conductive contact 114a and vertically between the first dielectric structure 302a and the resistive structure 112, and a second cavity 320b may be formed along a sidewall of the second conductive contact 114b and vertically between the second dielectric structure 302b and the resistive structure 112.

Thereafter, via openings are formed in the IMD layer and the dielectric structures 302. For example, a first via opening is formed extending vertically through the IMD layer and the first dielectric structure 302a to expose the first conductive contact 114a, and a second via opening is formed extending vertically through the IMD layer and the second dielectric structure 302b to expose the second conductive contact 114b. A conductive material (e.g., copper (Cu)) is formed on the IMD layer and in the via openings. The conductive material may be formed using a deposition process (e.g., CVD, PVD, sputtering, etc.) and/or a plating process (e.g., electrochemical plating, electroless plating, etc.). Thereafter, a planarization process (e.g., CMP) is performed on the conductive material and the IMD layer to form the first plurality of conductive vias 120 and the third IMD structure 118. Although not shown, it will be appreciated that any number of other conductive features (e.g., conductive lines and conductive vias) and/or IMD structures may be formed over the third IMD structure 118 and the first plurality of conductive vias 120.

Because the conductive contacts 114 are formed with larger footprints (e.g., due to the capping structures 116), the area (e.g., landing zones) in which the first plurality of conductive vias 120 must be formed on so that the first plurality of conductive vias 120 are electrically coupled to the conductive contacts 114 is also larger. In other words, the area in which the via openings must be aligned to land on the conductive contacts 114 is larger. Thus, it is easier to form the first plurality of conductive vias 120 on the conductive contacts 114. Accordingly, the capping structures 116 may reduce the cost to fabricate the IC comprising the resistor 101 (e.g., due to the larger footprints decreasing misalignment issues, thereby increasing device yield).

FIG. 11 illustrates a flowchart 1100 of some embodiments of a method for forming an IC comprising a resistor 101 disposed over a substrate 102. While the flowchart 1100 of FIG. 11 is illustrated and described herein as a series of acts or events, it will be appreciated that the illustrated ordering of such acts or events is not to be interpreted in a limiting sense. For example, some acts may occur in different orders and/or concurrently with other acts or events apart from those illustrated and/or described herein. Further, not all illustrated acts may be required to implement one or more aspects or embodiments of the description herein, and one or more of the acts depicted herein may be carried out in one or more separate acts and/or phases.

At act 1102, a resistive layer is formed over a substrate, a conductive layer is formed over the resistive layer, and a dielectric layer is formed over the conductive layer. FIGS. 5A-5B illustrate various views of some embodiments corresponding to act 1102.

At act 1104, a first patterning process is performed on the dielectric layer, the conductive layer, and the resistive layer to form a dielectric structure, a first conductive structure, and a resistive structure, respectively. FIGS. 6A-6B illustrate various views of some embodiments corresponding to act 1104.

At act 1106, a capping layer is formed over and covering the dielectric structure, the first conductive structure, and the resistive structure. FIGS. 7A-7B illustrate various views of some embodiments corresponding to act 1106.

At act 1108, a second patterning process is performed on the capping layer, the dielectric structure, and the first conductive structure to form capping structures, dielectric structures, and a second conductive structure, where the capping structures cover opposite outer sidewalls of the second conductive structure. FIGS. 8A-8B illustrate various views of some embodiments corresponding to act 1108.

At act 1110, a third patterning process is performed on the second conductive structure to form conductive contacts over the resistive structure. FIGS. 9A-9B illustrate various views of some embodiments corresponding to act 1110.

At act 1112, an inter-metal (IMD) structure is formed over the resistive structure, the conductive contact, the dielectric structures, and the capping structures. FIGS. 10A-10B illustrate various views of some embodiments corresponding to act 1112.

At act 1114, conductive vias are formed in the IMD structure, where the conductive vias are electrically coupled to the conductive contacts. FIGS. 10A-10B illustrate various views of some embodiments corresponding to act 1114.

In some embodiments, the present application provides an integrated chip (IC). The IC comprises a substrate. A resistor overlies the substrate. The resistor comprises a resistive structure overlying the substrate. The resistor also comprises a conductive contact overlying and electrically coupled to the resistive structure. A capping structure is disposed over the conductive contact, wherein the capping structure extends laterally over an upper surface of the conductive contact and vertically along a first sidewall of the conductive contact, such that a lower surface of the capping structure is disposed below a lower surface of the conductive contact.

In some embodiments, the present application provides an integrated chip (IC). The IC comprises a substrate. A first intermetal dielectric (IMD) structure overlies the substrate. A resistor overlies the first IMD structure. The resistor comprises a resistive structure overlying the first IMD structure. The resistor also comprises a first conductive contact overlying and electrically coupled to the resistive structure, wherein a sidewall of the first conductive contact is substantially aligned with a first sidewall of the resistive structure. A first capping structure is disposed over the first conductive contact, wherein the first capping structure covers an upper surface of the first conductive contact, and wherein the first capping structure extends vertically along both the sidewall of the first conductive contact and the first sidewall of the resistive structure.

In some embodiments, the present application provides a method for forming an integrated chip (IC). The method comprises forming a resistive layer over an inter-metal dielectric (IMD) structure. A conductive layer is formed over the resistive layer. The resistive layer and the conductive layer are patterned to form a resistive structure and a conductive structure, respectively. A capping layer is formed over the resistive structure and the conductive structure, wherein the capping layer is formed over an upper surface of the conductive layer, along sidewalls of the resistive structure, and along sidewalls of the conductive structure. The capping layer is patterned to form a capping structure over the conductive structure. The conductive structure is patterned to form a conductive contact over the resistive structure and below the capping structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1-20. (canceled)

21. An integrated chip (IC), comprising:
a substrate;
a resistor comprising:
a resistive structure overlying the substrate; and
a conductive contact overlying and electrically coupled to the resistive structure; and
a capping structure overlying and extending laterally along a top surface of the conductive contact and further extending vertically along a sidewall of the conductive contact, such that a bottom surface of the capping structure is recessed relative to a bottom surface of the conductive contact.

22. The IC according to claim 21, wherein an entirety of the conductive contact overlies the resistive structure.

23. The IC according to claim 21, wherein the capping structure further extends vertically along a sidewall of the resistive structure, such that the bottom surface of the capping structure is recessed relative to a bottom surface of the resistive structure.

24. The IC according to claim 23, wherein the sidewall of the conductive contact overlies and is edge to edge with the sidewall of the resistive structure.

25. The IC according to claim 23, wherein the capping structure vertically and directly contacts the top surface of the conductive contact and further laterally and directly contacts the sidewall of the conductive contact.

26. The IC according to claim 23, wherein the conductive contact has an additional sidewall that faces an opposite direction as the sidewall of the conductive contact, and wherein a cavity entirely underlies the capping structure at the additional sidewall of the conductive contact.

27. The IC according to claim 23, wherein the resistor further comprises:
an additional conductive contact overlying the resistive structure and spaced from the conductive contact along a length of the resistive structure, wherein a width of the resistive structure extends laterally transverse to the length of the resistive structure, and wherein the width of the resistive structure has a value at a length-wise center of the resistive structure that is less than a shared value of the width of the resistive structure at the additional conductive contact and the conductive contact.

28. An integrated chip (IC), comprising:
a substrate;
a first intermetal dielectric (IMD) structure overlying the substrate;
a resistor comprising:
a resistive structure overlying the first IMD structure; and
a first conductive contact overlying and electrically coupled to the resistive structure, wherein a first sidewall of the first conductive contact overlies and is substantially aligned with a first sidewall of the resistive structure; and
a first capping structure overlying a top surface of the first conductive contact and extending vertically along both the first sidewall of the first conductive contact and the first sidewall of the resistive structure.

29. The IC according to claim 28, wherein a length of the resistive structure extends from a first end of the resistive structure to a second end of the resistive structure opposite the first end of the resistive structure, and wherein the first capping structure is localized to the first end.

30. The IC according to claim 29, wherein the first conductive contact has a second sidewall facing an opposite direction as the first sidewall of the first conductive contact, and wherein the second sidewall of the first conductive contact is laterally between a first sidewall of the first capping structure and the first sidewall of the first conductive contact.

31. The IC according to claim 28, further comprising:
a first dielectric structure overlying the first conductive contact and underlying and the first capping structure, wherein the first dielectric structure, the first conductive contact, and the resistive structure form a first common sidewall, including the first sidewall of the first conductive contact and the first sidewall of the resistive structure, and wherein the first common sidewall is lined by the first capping structure.

32. The IC according to claim 31, wherein a width of the first dielectric structure is greater than a width of the first conductive contact.

33. The IC according to claim 28, further comprising:
a first dielectric structure overlying the first conductive contact and underlying and the first capping structure, wherein a first cavity underlies the first dielectric structure at a second sidewall of the first conductive contact.

34. The IC according to claim 28, wherein the resistor further comprises a second conductive contact overlying and electrically coupled to the resistive structure, and wherein the IC further comprises a second capping structure overlying the second conductive contact and laterally and directly contacting a second sidewall of the resistive structure that borders a first sidewall of the second conductive contact.

35. An integrated chip (IC), comprising:
a substrate;
a resistor comprising:
a resistive structure overlying the substrate; and
a first conductive contact and a second conductive contact overlying and electrically coupled to the resistive structure, wherein a sidewall of the first conductive contact and a sidewall of the second conductive contact face away from each other and are separated from each other by a distance that is substantially the same as a length of the resistive structure; and
a first capping structure and a second capping structure respectively overlying the first conductive contact and the second conductive contact and respectively extending along the sidewall of the first conductive contact and the sidewall of the second conductive contact.

36. The IC according to claim 35, wherein the first conductive contact and the second conductive contact are spaced from each other along the length of the resistive structure.

37. The IC according to claim 35, wherein the resistive structure has a first sidewall and a second sidewall respectively adjoining the sidewall of the first conductive contact and the sidewall of the second sidewall of the second conductive contact.

38. The IC according to claim 35, further comprising:
a conductive via overlying the first conductive contact and extending through the first capping structure from the first conductive contact.

39. The IC according to claim 35, further comprising:
an intermetal dielectric (IMD) structure overlying the resistor and the first and second capping structures, wherein the IMD structure extends to the resistive structure between the first and second capping structures to completely separate the first and second capping structures from each other.

40. The IC according to claim 39, wherein the first and second capping structures are spaced from each other along the length of the resistive structure with a first separation, and wherein the first and second conductive contact are spaced from each other along the length of the resistive structure with a second separation greater than the first separation.
